(19) United States
(12) Patent Application Publication
(10) Pub. No.: US 2025/0169274 A1
(43) Pub. Date: May 22, 2025

(54) CHIRAL BAND EDGE EMISSION ENHANCED ORGANIC LIGHT EMITTING DIODE-BASED DEVICES THAT EMIT MULTIPLE LIGHT WAVELENGTHS

(71) Applicant: Red Bank Technologies LLC, Red Bank, NJ (US)

(72) Inventors: John N. MAGNO, Newtown, PA (US); Gene C. KOCH, Corvallis, OR (US)

(21) Appl. No.: 18/841,118

(22) PCT Filed: Feb. 24, 2023
(86) PCT No.: PCT/US2023/063258

§ 371 Date: Aug. 23, 2024

Related U.S. Application Data
(60) Provisional application No. 63/313,794, filed on Feb. 25, 2022.

(51) Int. Cl. H10K 50/13; H10K 50/858; H10K 85/00

(52) U.S. Cl. CPC H10K 50/131; H10K 50/858; H10K 85/731

(57) ABSTRACT

A light emitting device is described. The light emitting device includes a single light emitting photonic crystal having an electroluminescent material disposed in the single light emitting photonic crystal. The single light emitting photonic crystal includes a series of layers of chiral liquid crystalline polymer. The electroluminescent material is localized in one of the layers of chiral liquid crystalline polymer. At least one of the series of layers of chiral liquid crystalline polymer includes a chiral liquid crystalline, charge carrier transporting polymer. The single light emitting photonic crystal further includes a second luminescent material, where energy emanating from the electroluminescent material stimulates the second luminescent material into light emission, and the light emitted by the light emitting device is a mixture of light emitted by the electroluminescent material and light emitted by the second luminescent material.

### CROSS-REFERENCE TO RELATED APPLICATIONS

This application claims priority to U.S. Patent Application No. 63/313,794, filed Feb. 25, 2022, the entire content of which is incorporated herein by reference.

### INTRODUCTION

### Background

U.S. Pat. No. 10,727,421 discloses light emitting photonic crystal devices (termed C-OLEDs) in which an organic light emitting diode (OLED) is embedded as a single zone or layer within a single one-dimensional photonic crystal. The OLED and the other organic material layers comprised by the one-dimensional photonic crystal all, in turn, comprise chiral liquid crystalline polymeric material. It is an intrinsic property of chiral liquid crystals that when they are uniformly aligned they function as one-dimensional photonic crystals, fluorescent dye. U.S. Pat. No. 10,727,421 explains his as follows. The structure of an aligned chiral liquid crystal is shown in FIG. 1. Rod shaped liquid crystal molecules 110 within layers 120 tend to align with their long axes pointing in single direction parallel to an axis called the director 130. In aligned nematic liquid crystals the director always points in the same direction. However, because of the asymmetric shape of some of the molecular constituents, in chiral liquid crystals as one passes down through the material along axis 140 as shown in FIG. 1, the direction of the director 130 rotates so as to sweep out a helix. Thus, the individual liquid crystal molecules combine into a helical structure. Because of the anisotropy of electronic polarization within the individual molecules, light of the proper circular polarization passing through the liquid crystalline material encounters a much higher refractive index when its associated electric vector is parallel to the molecules' long axes than when its electric vector is perpendicular to the molecules' long axes. Given that the light has the proper wavelength, light of the opposite circular polarization (for instance, right-handed versus left-handed) has its associated electric vector rotated so as to track the helical structure of the liquid crystal and thus sees no change in refractive index as it passes up through the chiral liquid crystalline structure. Thus, circularly polarized light of the correct handedness propagating parallel to axis 140 sees a periodically oscillating refractive index as it passes through molecules with their long axes oscillating between directions parallel and anti-parallel to the light's electric vector. In this way the assembly of chiral liquid crystalline molecules act as a one-dimensional photonic crystal material for one circular polarization of light along axis 140.

The functioning of the C-OLED devices relies on the formation of a “stop band” within the photonic crystal. The stop band is a range of light wavelengths for which solutions of the wave equation for the propagation of light do not exist. That is to say, a luminescent molecule embedded in the photonic crystal cannot emit light in the direction of the refractive index alternation within the photonic crystal structure. In photonic crystals of this type the center wavelength of the stop band has a value that is given by

$${λ}_{c} = ( {n}_{e} - {n}_{o} ) P / 2$$

wherein λ_{c} is the center wavelength of the stop band, nₑ is the extraordinary refractive index of nematic liquid crystalline polymer, no is the ordinary refractive index of the nematic liquid crystalline polymer and P is the pitch of the helical structure of the chiral liquid crystalline polymer.

The light emission function of the band-edge enhanced OLED devices depends upon the fact that within these devices an edge of the stop band 210 as portrayed in FIG. 2 (up to this time usually the short wavelength edge 220) overlaps the emission spectral band of the electroluminescent material within the OLED structure. As explained in U.S. Pat. No. 10,727,421 and illustrated in FIG. 2, it is a property of photonic crystals that the density of states at the band edge wavelengths of the stop band associated with the photonic crystal is substantially higher than that for the same wavelength in air or vacuum. The result is that the light emission of the electroluminescent material is considerably enhanced over what it would be in other media. In addition, a considerable portion of the light that is emitted in the band edge states or modes is retained within the photonic crystal structure bathing the photoluminescent molecules in a high luminous flux of light in the band edge wavelengths. This intense retained light stimulates additional light emission from other molecules of electroluminescent material that are in excited states due electrical excitation. Since the light that is emitted into the band edge modes of propagation is constrained to emission in a narrow band of angles about the normal to the surface of the C-OLED and since the stimulated emission replicates the propagation modes of the stimulating light radiation, the light is emitted by the C-OLED in a narrow cone of angles. The emission of light in a narrow cone of angles about the normal to the C-OLED's surfaces results in almost complete outcoupling of light from the C-OLEDs making them much more energy efficient than conventional OLEDs.

The very high energy efficiency and collimated light emission of C-OLEDs are very desirable for many applications. In addition, the narrow spectral emission bands of these devices can also be highly desirable when highly saturated colors are required in light emission. However, the narrow spectral emission bands are an issue if the intent is to use C-OLEDs in applications requiring white light. Some solutions to this problem have already been considered. The first is to situate multiple C-OLEDs emitting different colors adjacent to each other on the same substrate. Issues with this approach are its manufacturing complexity and that it is quite difficult to produce lamp optics that will blend the colors together so as to produce uniform light chromaticity over the whole range of light emission angles. U.S. Pat. No. 10,680,185 describes C-OLED-based devices in which luminescent materials are coated at an emissive surface of a C-OLED that emits shorter wavelength light (e.g. blue or violet). The light from the C-OLED is absorbed by the photoluminescent material producing photoluminescent emission from that material. The photoluminescent material used can emit white light. In this case the light emission is over a wide cone of angles and this can be undesirable in some applications. In addition, if some of the shorter wavelength light from the C-OLED leaks through the white photoluminescent top layer, the uniformity of light emission versus emission angle can suffer. If a sufficient thickness of the white photoluminescent material is coated to eliminate leakage of the C-OLED emitted light, the energy efficiency of the device can suffer due to light absorption in the photoluminescent material.

What is needed is a C-OLED-based device that emits light in a narrow cone of angles at multiple wavelengths (e.g. white light) and has uniform chromaticity over the range of angles at which it emits.

### SUMMARY

Embodiments include a light emitting device including a single light emitting photonic crystal having an electroluminescent material disposed in the single light emitting photonic crystal. The single light emitting photonic crystal includes a series of layers of chiral liquid crystalline polymer. The electroluminescent material is localized in one of the layers of chiral liquid crystalline polymer. At least one of the series of layers of chiral liquid crystalline polymer includes a chiral liquid crystalline, charge carrier transporting polymer. The single light emitting photonic crystal further includes a second luminescent material, where energy emanating from the electroluminescent material stimulates the second luminescent material into light emission, and the light emitted by the light emitting device is a mixture of light emitted by the electroluminescent material and light emitted by the second luminescent material.

### DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments and are therefore not to be considered limiting; other equally effective embodiments are contemplated.

FIG. 1 illustrates a structure of an aligned chiral liquid crystal, according to one embodiment.

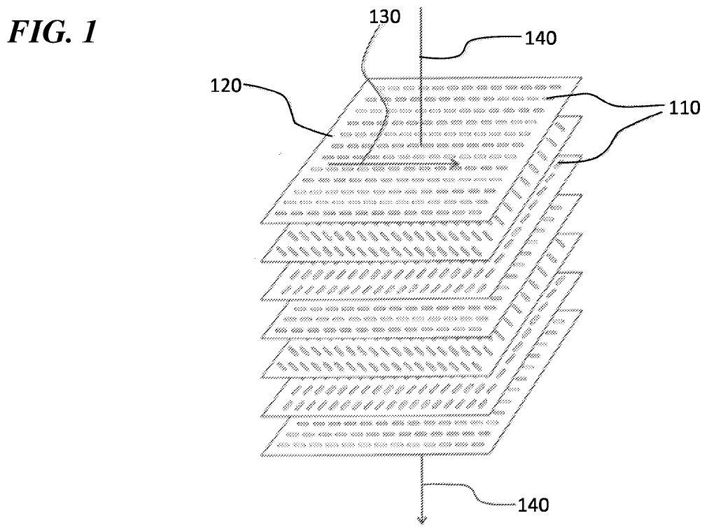

FIG. 2 illustrates light emission for a band-edge enhanced OLED device, according to one embodiment.

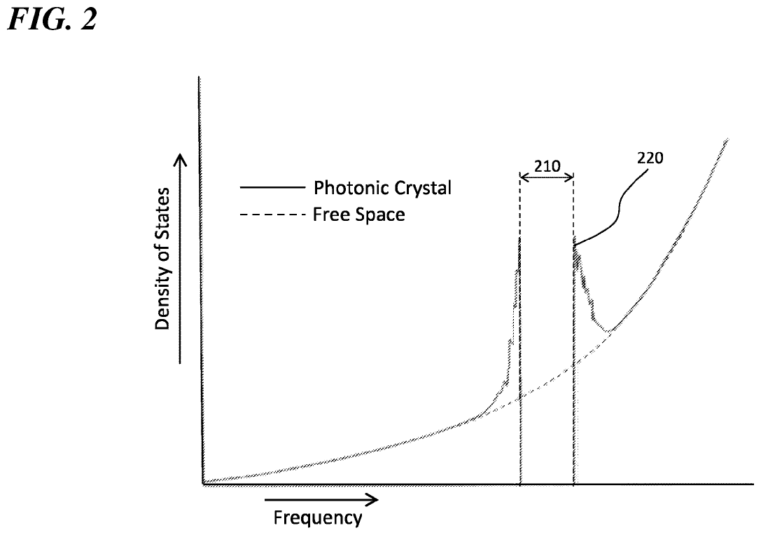

FIG. 3 illustrates an example light emitting device, according to one embodiment.

FIG. 4 illustrates a further example light emitting device, according to one embodiment.

FIG. 5 illustrates another example light emitting device, according to one embodiment.

FIG. 6 illustrates a chiral light emitting electrochemical cell (C-LEC), according to one embodiment.

FIG. 7 illustrates a chemical structure relating to light emitting materials, according to one embodiment.

To facilitate understanding, identical reference numerals have been used, where possible, to designate identical elements that are common to the figures. It is contemplated that elements disclosed in one embodiment may be beneficially used in other embodiments without specific recitation.

### DETAILED DESCRIPTION

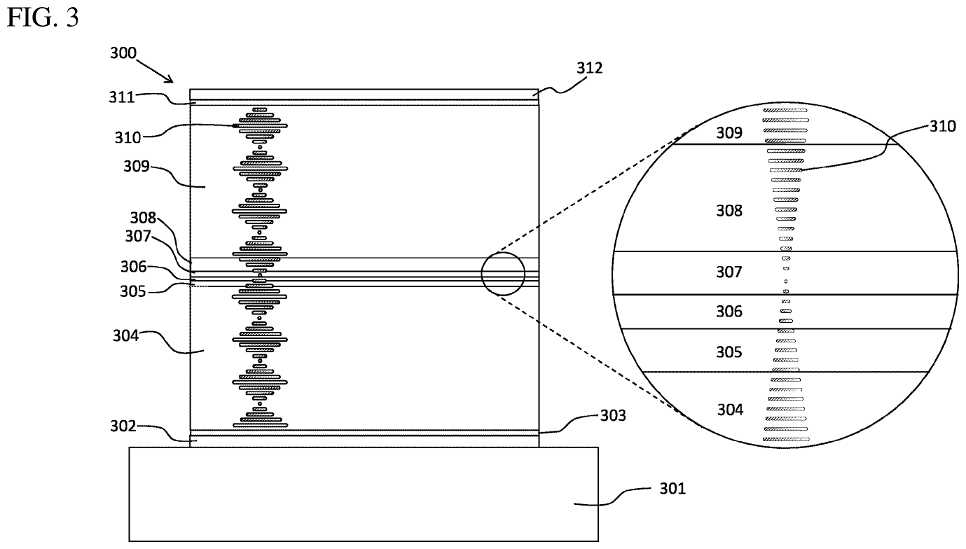

FIG. 3 depicts a series of embodiments 300 of the invention. Device 300 comprises a C-OLED similar to that described in U.S. Pat. No. 10,727,421, but with the addition of an additional layer 307. The device is built up layer by layer on a transparent substrate 301 composed of any suitable materials, for instance glass or clear plastic. First a clear, electrically conducting anode layer 302 is coated onto the substrate, most often by vacuum deposition. This anode layer may comprise a transparent semiconducting material such as indium zinc oxide or indium-tin oxide. Next a hole transporting, liquid crystal photoalignment layer 303 is coated onto the substrate surface. U.S. Pat. No. 7,118,787 and US Patent Application 2011/0020566 disclose various materials that can be used as such a hole transporting layer in various embodiments of a chiral liquid crystalline light emitting device. The details of layers used for this purpose are described in U.S. Pat. No. 10,727,421. The alignment layers 303 produces an anisotropic surface energy at the surface of the alignment layer that aligns liquid crystal molecules coated over it.

The next layer that may optionally be fabricated as shown in FIG. 3 is a p-doped hole transporting layer 304. The goal in the fabrication of this layer is to produce a relatively high conductivity film that minimizes the voltage drop between the anode and the emitter layer 306. This is accomplished by doping a monomeric chiral nematic liquid crystalline hole transporting material with a strongly electron accepting monomeric p-dopant.

In order to achieve a complete photonic stop band in a relatively thin layer of chiral material it is necessary that the chiral nematic monomers used to produce layer 304, shown in FIG. 3, and the other chiral liquid crystalline materials used to form layers in the device have a very high ratio of their extraordinary refractive indices to their ordinary refractive indices. This, in turn, means that their molecules' long axes be much longer than the molecules are wide. Examples of chiral nematic mixtures comprising such materials are given U.S. Pat. No. 10,727,421.

Since all of the chiral liquid crystalline polymer layers in the device need to be matched in terms of ordinary and extraordinary refractive indices, it may be necessary to introduce less birefringent liquid crystalline monomer materials into the mixture of materials in this layer to tune the refractive indices.

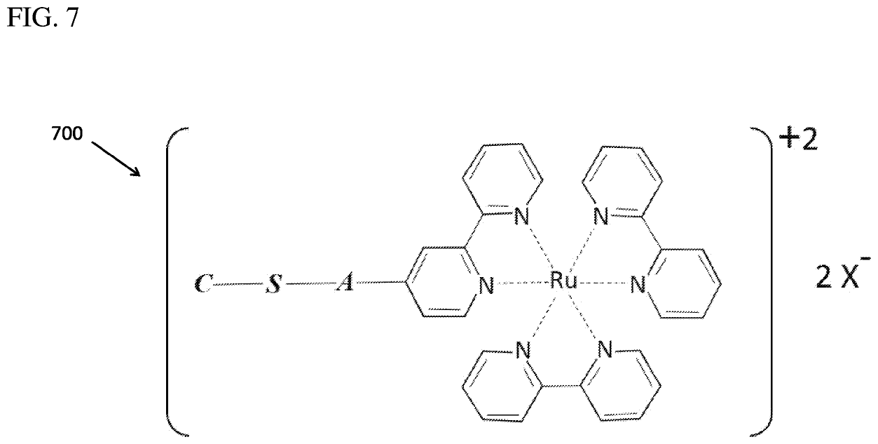

In order to produce a chiral liquid crystalline polymer of the required pitch, it is necessary to dope the monomer mixture used to produce layer 74 in FIG. 7 with a chiral dopant. Exemplary chiral dopants are described in U.S. Pat. No. 10,727,421.

Referring back to FIG. 3 the mixture of nematic liquid crystalline monomers and p-dopant(s) to be used to form layer 304 is solvent cast over the photoalignment layer 303 and solvent is allowed to evaporate off either at room temperature or an elevated temperature. Once the solvent is gone the material is in the form of a layer of chiral nematic liquid crystalline fluid or possibly a chiral nematic liquid crystalline glass. The anisotropic surface energy at the top surface of layer 303 induces the molecules of the chiral nematic material at the interface between layers 303 and 304 to be aligned with their molecular long axes surface parallel and with their molecular long axes all substantially in the same direction thus producing the desired helical structure in layer 304. The chiral liquid crystalline monomer mixture is then photopolymerized usually by UV light locking the helical liquid crystalline structure in place in a polymer matrix.

The next layer to be fabricated in the layer-by-layer process is the hole transporting layer 305. The function of this layer is to convey electrically conducting holes from p-doped layer 304 into second emitter layer 306. In doing so the holes transition in energy from the highest occupied molecular orbital (HOMO) levels in the conductive dopant in layer 304 to the HOMO energy levels of emitter layer 306. The layer is produced by the solvent casting of a solution of a mixture of chiral nematic liquid crystalline monomers in a manner similar to that used to produce layer 304 except that there is no p-dopant in the mixture. After the solvent used to cast the monomeric mixture evaporates away the material of the mixture forms a layer of chiral nematic liquid crystalline fluid or a chiral nematic glass on the top surface of layer 304. The liquid crystalline order of layer 304 provides a template such that the long axes of the molecules at the bottom surface of layer 305 are aligned parallel with the long axes of the nematic molecular cores of the polymeric material at the top surface of layer 304. In this way the helical structure induced by the chiral nature of the materials in layers 304 and 305 is continuous in passing across the interface between the two layers. Once the material of layer 305 is in place and properly aligned it is polymerized by exposure to ultraviolet light. The chiral nematic monomeric materials that are used to form layer 305 may be the same as were used to produce layer 304 except that the p-dopant is omitted. The exact chemical structure of the molecules used and their molecular lengths is dictated by the requirement that the ordinary and extraordinary refractive index components of the mixtures in the two layers must match each other and the helical pitches of the chiral nematic structures within the two layers must also be the same. Examples of chiral nematic mixtures comprising such materials are given U.S. Pat. No. 10,727,421.

The next layer to be fabricated by the layer-by-layer process is the second emitter layer 306. The second emitter layer 306 of the device may consist solely of a monomeric nematic luminescent material doped with a chiral additive to produce a helical structure of the proper pitch. Suitable luminescent nematic materials may be the electroluminescent materials disclosed in U.S. Pat. No. 10,727,421 and U.S. patent application Ser. No. 16/490,146. Preferably these materials should be hole transporting in nature. However, a more preferable formulation for the material in this layer is to utilize a luminescent dopant doped into a host composed of a mixture of monomeric chiral nematic materials. This approach has the advantages that the dopant concentration may be chosen so as to minimize self-absorption of light by the dopant. Non-liquid crystalline emitter materials such as phosphorescent emitters or laser dyes with very high quantum efficiencies may be utilized as dopants while maintaining the desired helical structure of the chiral host. It is preferred that the luminescent dopants be derivatized with one or more crosslinking groups. Some suitable dopants are described in U.S. Pat. No. 10,727,421. As was the case with layer 305, the nematic molecular order of the underlying nematic polymer layer (in this case layer 305) serves to properly align the molecules of layer 306 before they are photopolymerized.

Rays of light that are entrained in the helical photonic crystal structure have their associated electric vectors all oriented parallel to the planes of the device layers. As a result, this light will only interact with excited molecules whose transition moments are also substantially in the plane of the device. Therefore, luminescent materials in layer 306 whose molecules are preferentially oriented so that their transition moments are in the device plane will yield the highest device energy efficiencies (external quantum efficiencies) when used in the emitter layers of the devices of embodiments of this invention.

In various embodiments the second emitter layer 306 that is formed on top of the hole transporting layer 305 comprises a luminescent material having a emission spectrum and an absorption spectrum. The stop band of the photonic crystal comprising layers 304 through 309 is tailored by altering the pitch of the chiral nematic structure such that the long wavelength band-edge of the photonic crystal stop band overlaps the emission spectrum of the luminescent material comprised by layer 306. When device 300 is electrically activated, peak radiance wavelength of the long wavelength band-edge light emission measured normal to the device surface is a wavelength at which free space light emission of the luminescent material of layer 306 is preferably greater than ¼ and most preferably greater than ½ the peak luminescent radiance of the luminescent material. In addition, when device 300 is electrically activated, the peak radiance wavelength of the long wavelength band-edge light emission occurs at a wavelength at which the light absorption for a single pass of light through the second emitter layer is less than 1% preferably less than 0.5%.

The luminescent material-doped chiral nematic monomer mixture used to fabricate second emitter layer 306 should be blended from various chiral liquid crystalline components such that the chiral liquid crystalline polymer comprised by layer 307 has an ordinary refractive index, an extraordinary refractive index and a chiral pitch whose values vary from the corresponding values for the same parameters for chiral liquid crystalline polymer layers 304, 305, 307, 308 and 309 by less than 5% and preferentially the values for these three parameters should be the same for all layers 304 through 309. The materials used to prepare layer 306 may be the same as those in layer 305 except that luminescent material is added.

The next layer to be fabricated by the layer-by-layer process is the first emitter layer 307. The first emitter layer 307 of the device may consist solely of a monomeric nematic electroluminescent material doped with a chiral additive to produce a helical structure of the proper pitch. Suitable electroluminescent nematic materials are disclosed in U.S. Pat. No. 10,727,421. However, a more preferable formulation for the material in this layer is to utilize an electroluminescent dopant doped into a host composed of a mixture of monomeric chiral nematic materials. This approach has a number of advantages, for example, the dopant concentration may be chosen so as to minimize self-absorption of light by the dopant; the monomeric host chiral nematic materials may be blended to produce a mixture that is ambipolar, that is to say, electron and hole mobilities are approximately equal; and non-liquid crystalline emitter materials such as phosphorescent emitters with very high quantum efficiencies may be utilized as dopants while maintaining the desired helical structure of the chiral host. Suitable dopants are described in U.S. Pat. No. 10,727,421 and U.S. patent application Ser. No. 16/490,146. As was the case with layer 306, the nematic molecular order of the underlying nematic polymer layer (in this case layer 306) serves to properly align the molecules of layer 307 before they are photopolymerized.

Rays of light that are entrained in the helical photonic crystal structure have their associated electric vectors all oriented parallel to the planes of the device layers. As a result, this light will only interact with excited molecules whose transition moments are also substantially in the plane of the device. Therefore, electroluminescent materials in layer 307 whose molecules are preferentially oriented so that their transition moments are in the device plane will yield the highest device energy efficiencies (external quantum efficiencies) when used in the emitter layers of the devices of embodiments of this invention.

In various embodiments the first emitter layer 307 that is formed on top of the second emitter layer 306 comprises an emitter material having a emission spectrum and an absorption spectrum. The stop band of the photonic crystal comprising layers 304 through 309 is tailored by altering the pitch of the chiral nematic structure such that the short wavelength band-edge of the photonic crystal stop band overlaps the emission spectrum of the emitter material comprised by layer 307. When device 300 is electrically activated, peak radiance wavelength of the short wavelength band-edge light emission measured normal to the device surface is a wavelength at which free space light emission of the emitter material is preferably greater than ¼ and most preferably greater than ½ the peak radiance of the emitter. In addition, when device 300 is electrically activated, the peak radiance wavelength of the band-edge light emission occurs at a wavelength at which the light absorption for a single pass of light through the first emitter layer is less than 1% preferably less than 0.5%.

The emitter-doped chiral nematic monomer mixture used to fabricate first emitter layer 307 should be blended from various chiral liquid crystalline components such that the chiral liquid crystalline polymer comprised by layer 307 has an ordinary refractive index, an extraordinary refractive index and a chiral pitch whose values vary from the corresponding values for the same parameters for chiral liquid crystalline polymer layers 304, 305, 306, 308 and 309 by less than 5% and preferentially the values for these three parameters should be the same for all layers 304 through 309. First emitter layer 307 has a thickness that is 10% or less of the total combined thicknesses of layers 304 through 309.

The next device layer to be fabricated is the electron transporting layer 308. The function of this layer is to convey electrons from n-doped electron transporting layer 309 into first emitter layer 307. In doing so the electrons transition in energy from the electron energy levels in the conductive dopant in layer 309 to the HOMO energy levels of first emitter layer 307. The layer is produced by the solvent casting of a solution of a mixture of chiral nematic liquid crystalline monomers in a manner similar to that used to produce previous layers. After the solvent used to cast the monomeric mixture evaporates away, the material of the mixture forms an aligned layer of chiral nematic liquid crystalline fluid or a chiral nematic glass due to the template effect from the underlaying layer. In this way the helical structure induced by the chiral nature of the materials in layer 308 and all the previous layers in the device is continuous in passing across the interfaces between the two layers. The helical structure is polymerized so as to lock it into place by exposure to UV light. Chiral nematic monomers that may be used to fabricate layer 308 are disclosed in U.S. Pat. No. 10,727,421.

The next device layer to be fabricated is the n-doped electron transporting layer 309. The function of this layer is to convey electrons from the cathode 312 or possibly from an optional electron injection layer 311 into the electron transporting layer 308. In doing so the electrons transition in energy from the electron energy level of the cathode work function to the lowest unoccupied molecular orbital (LUMO) energy levels of the electron transporting layer 308. The layer is produced by the solvent casting of a solution of a mixture of chiral nematic liquid crystalline monomers in a manner similar to that used to produce previous layers. The layer also incorporates an n-dopant, such as the dopant (4-(1,3-dimethyl-2,3-dihydro-1H-benzoimidazol-2-yl)phenyl)dimethylamine (N-DBMI), which is activated by heating after the film is solvent cast.

Layer 309 may fabricated using the same mixture of monomeric nematic materials as were used for layer 308 with the n-dopant added. After the solvent used to cast the monomeric mixture evaporates away, the material of the mixture forms an aligned layer of chiral nematic liquid crystalline fluid or a chiral nematic glass due to the template effect from the underlaying layer. In this way the helical structure 310 induced by the chiral nature of the materials in layer 309 and all the previous layers in the device is continuous in passing across the interfaces between the two layers. The helical structure is polymerized so as to lock it into place by exposure to UV light.

Optionally layer 309 may be capped with an electron injection layer 311. Layer 311, for example, may comprise lithium fluoride or cesium carbonate. Layer 312 is a cathode and may, for example, be made from a low work function metal such as aluminum, magnesium/silver alloy, samarium or calcium.

When device 300 is energized, holes flow from anode 302 through hole injection layer 303 and layers 304, 305 and 306 into first emitter layer 307. At the same time electrons flow from cathode layer 312 through layers 311, 309 and 308 into first emitter layer 307. The electrons and holes recombine on electroluminescent material molecules in first emitter layer 307 yielding excitons. Since first emitter layer 307 is inside a photonic crystal structure, excitons created in that layer cannot emit light at wavelengths in the stop-band of the photonic crystal. However, where the emission band of the electroluminescent material in layer 307 overlaps the short wavelength band-edge wavelengths of the stop-band, light emission does occur and because of the high density of states at those wavelengths unusually high levels of emission occur. The photonic crystal traps the light from band-edge emission within its structure increasing the photon density to the point where there are sufficient photons to interact with excitons to the extent that nearly all light emission in layer 306 is stimulated emission. There may be, however, an insufficient level of stimulated emission to produce lasing. Since the light from stimulated emission is almost completely vertical in its direction of propagation within the device, there is very little loss due to internal reflection and trapping of light.

Some of the excited state energy of the electroluminescent material molecules in layer 307 is transferred to luminescent material molecules in second emitter layer 306. This energy transfer may be mediated by Förster or Dexter excitonic energy transfer mechanisms, or light emitted by the electroluminescent material in layer 307 may be absorbed by the luminescent material in layer 306. When this energy is transferred excitons are created in the luminescent material in layer 306. Since second emitter layer 306 is inside a photonic crystal structure, excitons created in that layer cannot emit light at wavelengths in the stop-band of the photonic crystal. However, where the emission band of the luminescent material in layer 306 overlaps the long wavelength band-edge wavelengths of the stop-band, light emission does occur and because of the high density of states at those wavelengths unusually high levels of emission occur. The photonic crystal traps the light from band-edge emission within its structure increasing the photon density to the point where there are sufficient photons to interact with excitons to the extent that nearly all light emission in layer 306 is stimulated emission. There may be, however, an insufficient level of this stimulated emission to produce lasing. Since the light from stimulated emission is almost completely vertical in its direction of propagation within the device, there is very little loss due to internal reflection and trapping of light. Because of the similar mechanism of light emission from layers 306 and 307, the angular distributions of light emission at the short and long band-edge wavelengths are the same or very nearly the same. If the mechanism of energy transfer from the electroluminescent material in layer 307 to the luminescent material in layer 306 is a Förster or Dexter mechanism, the light emission from second emitter layer 306 is due to electroluminescence and the luminescent material in layer 306 is an electroluminescent material. If the energy transfer mechanism is that of light emission from layer 307 and then light absorption in layer 306, the light emission from second emitter layer 306 is due to photoluminescence and the luminescent material in layer 306 is a photoluminescent material. The energy transfer between layers 307 and 306 may be due to two of or all three of the energy transfer mechanisms listed above or all three.

Förster and Dexter energy transfer mechanisms are relatively short range. Because of this, when these mechanisms are important contributors to energy transfer, second emitter layer 306 needs to be directly adjacent to first emitter layer 307 and layer 306 may need to be quite thin, e.g. less than ten nanometers in thickness. If the energy transfer is through light emission and then reabsorption, the second emitter layer 306 may be more remote from layer 307 so long is it is sufficiently near the center of the photonic crystal to be exposed to sufficient retained photon levels to promote stimulated emission. It may also be advantageous, given Förster or Dexter energy transfer, to omit second emitter layer 306 and to locate the luminescent material that would have been in this layer in first emitter layer 307 as a component in addition the electroluminescent material already present.

Light from emitter layers 306 and 307 that passes through layers 308, 309 and optionally 311 is reflected by the reflective metal cathode 312 back into the photonic crystal structure. Light from emitter layers 306 and 307 that passes through layers 305 and 304 and exits the device 300 through layers 303 and 302 and transparent substrate 301.

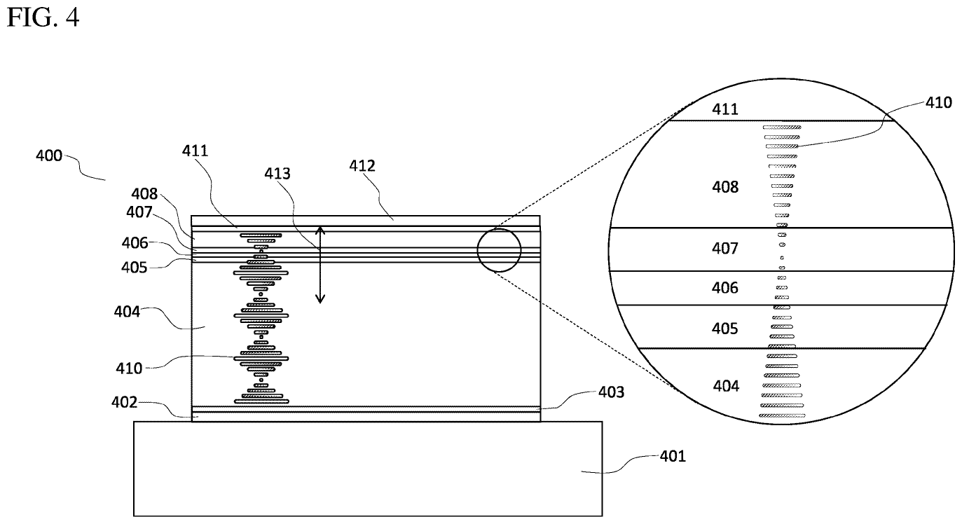

Other embodiments of the invention are illustrated in FIG. 4. Device 400 is similar to device 300, but different. Substrate 401 and layers 402, 403, 404, 405, 406, 407 and 408 (the anode layer; the hole transporting, liquid crystal photoalignment layer; the p-doped hole transporting layer, the hole transporting layer, the second emitter layer, the first emitter layer, and the electron transporting layer respectively) all perform the same functions as their counterparts, layers 302 through 308 in device 300. In addition, the reflective metal layer cathode layer 412 and the optional electron injection layer 411 also perform the same function as the corresponding layers 312 and 311 in device 300. However, an n-doped electron transporting layer analogous to layer 309 in device 300 is missing from device 400.

A cursory examination of FIG. 4 would seem to indicate that device 400 would not function nearly as well as device 300 because emitter layers 406 and 407 appear to be at an edge of helical structure 410 and the helical structure may not be thick enough to create a stop band. However, this is not the case. This can be explained by examining the path of a light ray 413 at a wavelength at the short wavelength band-edge of the stop band that is emitted in layer 407, travels towards transparent substrate 401, but is reflected back by the helical structure 410. The light ray then traverses back through layers 405, 406, 407, 408 and optionally 411 to be reflected by metallic reflector (cathode) 412. At the reflector 412 the light ray is reflected back through the helical structure 410 that comprises layers 408, 407, 406, 405 and 404. What the light ray “sees” along this path a structure equivalent to photonic crystal structure 310 in FIG. 3. Thus, the helical structure 410 in combination with reflector 412 acts as a photonic crystal that produces a stop band. The same sort of analysis applies to light emitted from layer 406.

As was the case with device 300, energy transfer from layer 407 to layer 406 can occur through three different mechanisms, Förster or Dexter excitonic energy transfer mechanisms, or light emitted by the electroluminescent material in layer 407 may be absorbed by the luminescent material in layer 406. If Förster or Dexter energy transfer are relied upon, layer 406 needs to be directly adjacent to layer 407 and layer 406 may need to be quite thin, e.g. less than ten nanometers in thickness. If the energy transfer is through light emission and then reabsorption, the second emitter layer 406 may be more remote from layer 407 so long is it is sufficiently near the center of the photonic crystal to be exposed to sufficient retained photon levels to promote stimulated emission. It may also be advantageous, given Förster or Dexter energy transfer, to omit second emitter layer 306 and to locate the luminescent material that would have been in this layer into first emitter layer 307 as a component in addition the electroluminescent material already present.

In both devices 300 and 400 the electroluminescent material in the first emitter layer (307 or 407) may yield exciplex emission. In this case the emissive material will be a mixture of an electron rich and an electron deficient material. Also, in this case, it may be advantageous to have the luminescent material that would otherwise be in layers 306 or 406 be in layers 307 or 407 with layers 306 or 406 eliminated.

The devices described above emit light at two wavelengths. The wavelengths arc determined by the position of the stop band in the electromagnetic spectrum and its width. A great advantage of the use of the chiral nematic helical structure to produce the stop band is that the width of the stop band can be tuned over a wide range of wavelengths and thus the chromaticity of the light produced by mixing the two wavelengths can be tuned over many locations in the CIE color space. The width of the stop band is given by:

$$Δλ = P ( {n}_{e} - {n}_{o} )$$

where Δλ is the width of the stop band, P is the chiral pitch, n_{c} is the extraordinary refractive index of the liquid crystal and no is the ordinary refractive index of the liquid crystal.

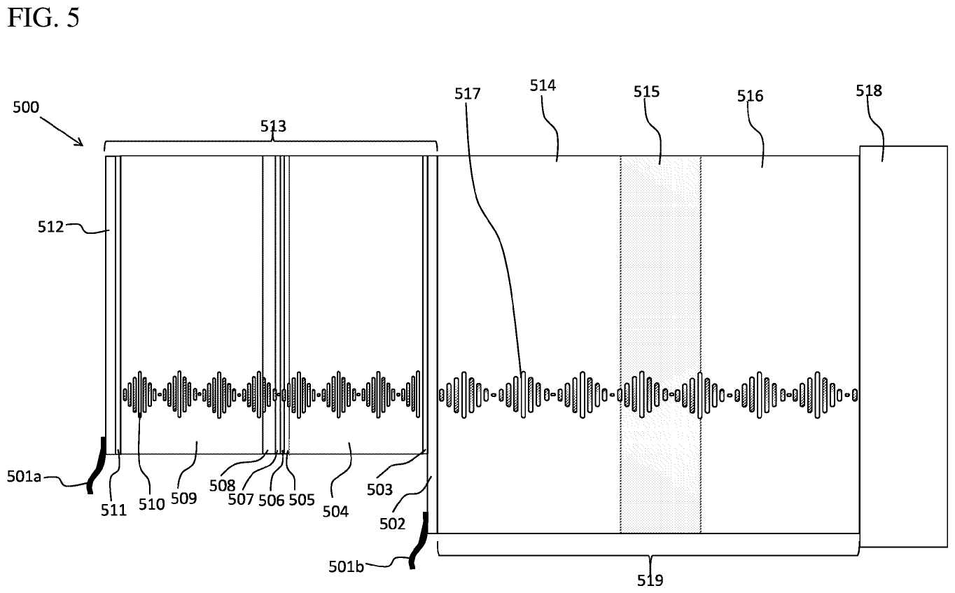

As a first example, if P=300 nm., ne=1.75 and no=1.5, the light emission wavelengths would be 450 nm, and 525 nm. As a second example, if P=300 nm., ne=1.8 and no=1.5, the light emission wavelengths would be 450 nm, and 540 nm. The second example yields two wavelengths that can be mixed to produce white light. The first example yields blue and green wavelengths. A device with the parameters used in the first example can be used in yet another embodiment of the invention, device 500 shown in FIG. 5, to yield RGB white light emission. In device 500 layers 503, 504, 505, 506, 507, 508, 509, 511, and 512 perform the same function as layers 303, 304, 305, 306, 307, 308, 309, 31, and 312 in device 300. Anode 502 functions in the same manner as anode 302 in device 300 except that anode 502 extends outward from stack 513 to allow interconnection to a electrical current source. Connection means 501a and 501b connect to cathode 512 and anode 502 so as to allow electrical current to flow into stack 513. Helical structure 510 has a pitch (for instance, 300 nm.), and the electroluminescent material in first emitter layer 507 and the luminescent material in second emitter layer 506 emit at light wavelengths in free space such that when these materials and layers are incorporated into layer stack 513 and the stack is energized through cathode 512 and anode 502, this stack emits light at blue and green wavelengths. Light produced in stack 513 leaves through transparent anode 502 and enters stack 519.

Stack 519 comprises three layers: the first transparent chiral nematic liquid crystalline polymer layer 514, the chiral nematic liquid crystalline polymer layer doped with a photoluminescent material 515, and the second transparent chiral nematic liquid crystalline polymer layer 516. All three of these layers comprise helical structure 517 produced in the chiral nematic material. These layers are built up sequentially, one at a time, on substrate 518 by depositing layers of chiral nematic monomer and then photocrosslinking them. Each succeeding layer has its molecules aligned by the anisotropic surface energy of the preceding layer. Once stack 519 is in place on substrate 518, stack 513 is built up on top of it.

Because of helical structure 517, stack 519 acts as a one-dimensional photonic crystal. The pitch of the helical structure 517 and the refractive indices of the materials used to produce layers 514, 515 and 516 are chosen to yield a photonic crystal stop band that has a short wavelength band edge in the red portion of the visible light spectrum, e.g. at 650 nm. The photoluminescent material doped into layer 515 is chosen so that its luminescent light emission spectrum overlaps the short wavelength band edge of the photonic crystal stop band. A portion of the blue and green light exiting stack 513 is absorbed by the photoluminescent material in layer causing it to emit red light. In this way, device 500 emits red, green and blue light. By tuning the ratios of the concentrations of the luminescent materials present in layers 506, 507 and 515 the chromaticity of the light emitted by device 500 can be tuned across most of the hues in the CIE 1931 color space. The nematic liquid crystalline monomer materials and chiral dopants used to formulate the liquid crystalline mixtures that are used to fabricate layers 514, 515, and 516 are chosen to ensure that the helical pitch of structure 517, and the ordinary and extraordinary refractive indices of the liquid crystalline material in layers 514, 515 and 516 are all within 10% of the values required to produce the desired photonic crystal stop band. Since the light of all three wavelengths emitted is produced in a similar manner by stimulated emission and all emitted in a narrow cone of angle vertically, there is little angular variation in chromaticity in the light emitted by device 500.

Another embodiment of the invention can be produced by replace layer stack 513 in device 500 with the layer stack of device 400 excluding substrate 401.

It is preferred that the photoluminescent dopant in stack 519 be confined to layer 515, but layers 514, 515 and 516 may be replaced by a single thicker layer of polymerized chiral nematic material that is uniformly doped with a photoluminescent material.

In another embodiment of the invention two photoluminescent materials are doped into layer 515 of device 500. One of these materials has an emission spectrum that overlaps the short wavelength band edge of the stop band associated with helical structure 517 and the second overlaps the long band edge of the same stop band. As an example, if the pitch of the helical structure 517 is 4009 nm, and the ordinary and extraordinary refractive indices of the liquid crystalline polymer in stack 519 are 1.5 and 1.76, the band edges of the stop band will be at 554 nm, and 651 nm. A device with these emission wavelengths may be advantageous because the human eye has its peak sensitivity to light at 555 nm.

In the descriptions of various embodiments above, when the emission spectrum of a luminescent material is said to overlap the short or long wavelength band edges of a photonic crystal stop band, it is preferred that the band edge is located at a wavelength where the intensity of light emission from the luminescent material is one-half or greater of the intensity of light emission at the wavelength of maximum intensity light emission. It is also preferred that the band edge wavelength is on long wavelength side of the luminescent material's emission band from the wavelength of maximum intensity light emission. This may not be the case if the luminescent light emission is from an exciplex species formed by two by the temporary association of two molecular species.

The molecules of the nematic monomers used to produce the various chiral nematic liquid crystalline polymers used in the layers comprised by the above embodiments may have structures represented by the formula

B-S-A-S-B

wherein B is a crosslinking group and preferably a crosslinking group crosslinkable by exposure to ultraviolet radiation, S is a flexible spacer, and A is a rigid or semi-rigid molecular core and preferably a chain of aromatic diradicals linked together in a linear fashion.

The core group A in some embodiments may be represented by the formula:

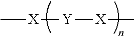

wherein X is an aromatic diradical or a single bond, Y are aromatic diradicals that may in each occurrence be independently represented by:

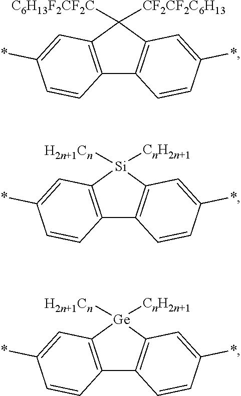

or
Y may be from a single bond as well so long as at least one Y is not a single bond, n is an integer between 1 and 5, and * represents a point connection to the rest of the molecule.

In the formula:

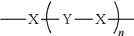

X in each occurrence may independently represent one of: 1,4-phenylene, biphenyl-4,4′-diyl, terphen-4,4″-diyl, naphthalene-1,4-diyl, naphthalene-2,5-diyl, thiophene-2,5-diyl, pyrimidine-2,5-diyl, perylene-3,10-diyl, pyrene-2,7-diyl, 2,2′-dithiophen-5,5′-diyl, oxazole-2,5-diyl, oxazole-2,4-diyl, 1,3,4-oxadiazole-2,5-diyl, 1,2,4-oxadiazole-3,5-diyl, thiazole-2,5-diyl, thiazole-2,4-diyl, 1,3,4-thiadiazole-2,5-diyl, 1,2,4-thiadiazole-3,5-diyl, thieno[3,2-b]thiophene-2,5-diyl, dithieno[3,2-b:2′,3′-d]thiophene-2,6-diyl, thiazolo[5,4-d]thiazole-2,5-diyl, oxazolo[5,4-d]oxazolc-2,5-diyl, thiazolo[5,4-d]oxazolc-2,5-diyl, thiazolo[4,5-d]thiazole-2,5-diyl, oxazolo[4,5-d]oxazole-2,5-diyl, thiazolo[4,5-d]oxazole-2,5-diyl, 2,1,3-benzothiadiazole-4,7-diyl, imidazo[4,5-d]imidazole-2,5-diyl, 9-alkyl(9H-carbazole)-2,7-diyl, carbazole-4,9-diyl, 9,9′-dialkyl-2,2′-bi (9H-carbazole-7,7′-diyl, 5,11-dialkyl(5,11H-indolo[3,2-b]carbazole)-3,9-diyl, dibenzo[b,d]thiophene-3,7-diyl, 5,5-dioxodibenzo[b,d]thiophene-3,7-diyl, benzo[b]naphtho[1,2-d]thiophene-3,9-diyl, 7,7-dioxobenzo[b]naphtho[1,2-d]thiophene-3,9-diyl, dinaphtho[1,2-b:2′,1′-d]thiophene-3,10-diyl, 13,13-dioxodinaphtho[1,2-b:2′,1′-d]thiophene-3,10-diyl, dinaphtho[1,2-b:2′,3′-d]thiophene-3,10-diyl, benzo[b]thieno[3,2-b]benzo[b]thiophene-3,8-diyl, 5,5-dioxo benzo[b]thieno[3,2-b]benzo[b]thiophene-3,8-diyl, bisbenzo[b]thieno[2,3-a:2,3-d]benzene-3,9-diyl. 5,5-dioxobisbenzo[b]thieno[2,3-a:2,3-d]benzene-3,9-diyl, 5,5,11,11-tetraoxobisbenzo[b]thieno[2,3-a:2,3-d]benzene-3,9-diyl, bisthieno[2,3-a:2,3-d]benzene-2,6-diyl, bisthieno[2,3-b:2,3-g]naphthalene-2,7-diyl or other diradicals or a single bond.

In more detail the complete molecules of the nematic monomers used to produce the various chiral nematic liquid crystalline polymers used in the layers comprised by the above embodiments may have structures represented by the formula:

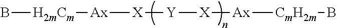

wherein the symbols B, X, Y, and n have the same meanings as discussed above. —CₘH₂ₘ— represents an alkanediyl diradical, and preferably an n-alkanediyl diradical, for instance n-pentane-1,5-diyl or n-decane-1,10-diyl. The value of m is an integer between 3 and 12 chosen independently for each occurrence. Ax represents a connecting unit that attaches the flexible spacer to the more rigid molecular core. Examples of Ax units are —O—, —S—, carboxyl groups, and carbonato groups chosen independently for each occurrence. The crosslinking groups B may be methacrylates, maleimides or vinyl ethers.

The chiral nematic monomer dopants used to formulate the chiral nematic mixtures used to produce the various chiral nematic liquid crystalline polymers used in the layers comprised by the above embodiments may have molecules with the formula:

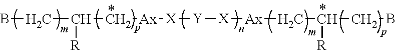

wherein B, X, Y and n have the meanings as discussed above. R are independently chosen from methyl, ethyl, n-propyl and isopropyl groups, m+n equals an integer between 3 and 12, and * denotes a chiral center (that is to say a center of asymmetry).

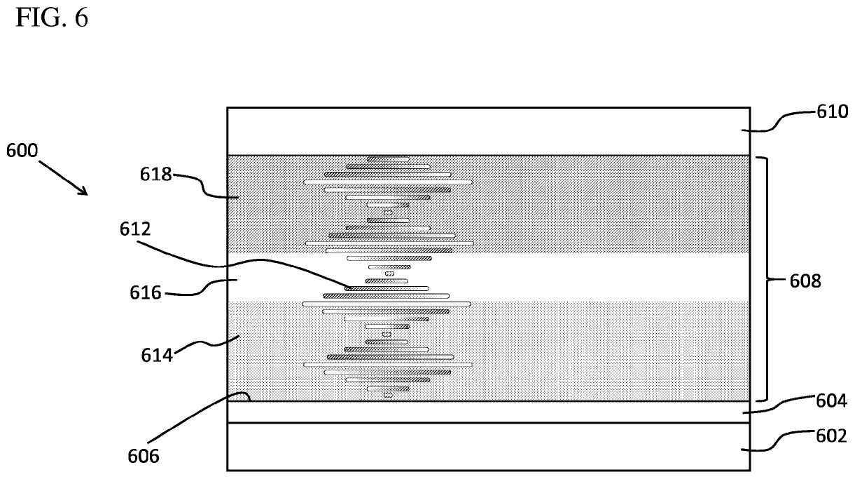

Another embodiment of the patent is portrayed in FIG. 6. This device 600 looks the same as a device described in US Patent Application Publication 2021/0119151, a chiral light emitting electrochemical cell. However, the device described here has significant differences.

The chiral light emitting electrochemical cell (C-LEC) 600 comprises a first electrode 602 that may be formed either from a light transmissive material or a light reflective material. If the first electrode 602 is light transmissive, it may be formed from indium-tin oxide, tin oxide, graphene or some other suitable light transmissive material. If the first electrode 602 is light reflective, it may be formed from aluminum, a magnesium/silver alloy or some other suitable light reflective material.

The inventive C-LEC 200 further comprises a conductive liquid crystal alignment layer 604 that is formed on the surface of the first electrode 602. This layer 604 conducts electric charge carriers from first electrode through to the chiral liquid crystalline organic material layer 608. This layer 604 further has the property that when a layer of liquid crystalline fluid material is formed on its upper surface 606, the rod-shaped molecules of the liquid crystal fluid material adjacent to the surface of layer 604 will be uniformly aligned with their long axes all oriented in the same direction (as much as random thermal oscillation in the liquid crystalline phase will allow) and also with their long axes parallel to the surface 606 of liquid crystal alignment layer 604. The conductive liquid crystal alignment layer 604 may be a rubbed layer of poly(3,4-ethylenedioxythiophene) polystyrene sulfonate (PEDOT:PSS), a conductive liquid crystal photoalignment layer like those described in U.S. Pat. No. 9,508,942, or other electrically conductive liquid crystal alignment layers as are known in the art.

The inventive C-LEC 600 further comprises a chiral liquid crystalline organic material layer 208. This layer has chiral liquid crystalline structure in which rod-shaped molecules within the layer are oriented with their long axes parallel to the surface 606 and with the direction of their long axes twisting in a helical fashion as one passes upwards through layer 608. This arrangement is depicted schematically (but on a much enlarged scale) by the arrangement of rod-shaped objects 612. It is preferred that this arrangement results from the material of layer 608 having chiral nematic (also termed cholesteric) liquid crystalline order. The material of layer 608 may be a liquid crystalline fluid, but it is preferred that the material be a solid. If the material is a solid it may be a chiral liquid crystalline glass, but it is further preferred that the material be a polymer formed by polymerizing a layer comprising chiral liquid crystalline fluid precursor monomer material into a polymer with the chiral liquid crystalline structure locked into place by crosslinking of molecules, It is preferred that the polymerization of the precursor monomer be accomplished by exposure to radiation and further preferred that the radiation be ultraviolet light. The material of layer 608 comprises an electroluminescent component material and a second luminescent component material.

The C-LEC 600 further comprises a second electrode 610. The second electrode 610 may be formed either from a light transmissive material or a light reflective material. However, if first electrode 604 is formed from a light reflective material, second electrode 610 must be formed from a light transmissive material. If the second electrode 610 is light transmissive, it may be formed from indium-tin oxide, tin oxide, graphene or some other suitable light transmissive material. If the second electrode 610 is light reflective, it may be formed from aluminum, a magnesium/aluminum alloy or some other suitable light reflective material.

When an electrical potential is placed across LEC 600 by voltage biasing one of the electrodes, 602 and 610, versus the other one of the two electrodes will act as an anode and one as a cathode. Either of the first or second electrodes may act as an anode or cathode. (In the example shown in FIG. 6 electrode 602 is taken to be the anode and electrode 610 is taken to be the cathode.) A component material of chiral liquid crystalline organic material layer 608 functions as an electrolyte. Molecular species in layer 608 will be oxidized to positive ions at the anode 602 and will be reduced to negative ions at the cathode 610. The material of region 618 adjacent to the cathode 610 acts as though it has been negatively doped. The material of region 614 adjacent to the anode acts as though it has been positively doped. As the electric potential difference across the layer 608 is increased the “doped” layers grow inwards from the electrodes towards the center of layer 608. The doped regions act in a manner similar to the electrodes in an OLED injecting holes (from the “doped” material region 618 near the cathode 610) and injecting electrons (from the “doped” material region 614 near the anode 602) into the “undoped” material in the region 616 in the center of the chiral liquid crystalline organic material layer 608.

When the electrons and holes are injected from regions 618 and 614 respectively into region 616, they recombine to form excitons on electroluminescent component molecules of chiral liquid crystalline organic material in layer 608 at the center of region 616. These excitons collapse to emit light.

As was described above, the organic material of layer 608 that has a chiral liquid crystalline structure comprises rod-shaped molecular cores that spontaneously align themselves in a helical structure because of their chiral liquid crystalline order. The liquid crystalline material in layer 608 is optically anisotropic with the refractive index (n_{c}) for light with its associated electric vector in the direction of the long axes of the rod-shaped molecules being higher in value than the refractive index (no) for light with its associated electric vector in one of the directions perpendicular to the long axis direction of the rod-shaped molecules. The light emitted by electroluminescent component material of layer 608 in the center of zone 616 encounters the helical structure 612 of layer 608. As described in previous embodiments described above, the helical structure 612 functions as a photonic crystal.

The helical pitch of the material in layer 608 that has chiral liquid crystalline structure is designed so that the short wavelength stop band edge of photonic crystal overlaps the emission band of the electroluminescent component in layer. When device 600 is energized by electrical current flowing between anode 602 and cathode 610 some of the energy of excitation produced on the electroluminescent component molecules of layer 608 is transferred to the second luminescent material in layer 608 causing it to emit light. The helical pitch of the material in layer 608 and the ordinary and extraordinary refractive indices of the material in layer 608 are chosen using the equations

$${λ}_{c} = ( {n}_{e} - {n}_{o} ) P / 2 and Δλ = P ( {n}_{e} - {n}_{o} )$$

so that the long wavelength stop band edge of the photonic crystal overlaps the emission band of the second luminescent material. In this way, the C-LEC device may be configured to emit two wavelengths of light due to stimulated emission of light at the two band edges. If the parameters of the material in layer 608 are properly chosen blue and yellow light may be emitted yielding light emission from the device that appears yellow.

It can be seen by the above description that the material in layer 608 performs multipole functions, an electrolyte, a chiral liquid crystalline material, an electroluminescent emitter, and a second luminescent material. Some of these functions may be combined in a single material component. An example is that of the compounds who molecular structures are symbolized in FIG. 7. These are ruthenium II containing electrolyte and light emitting materials having the generic structure 700. Here A is rigid, rod or lath-shaped aromatic moiety, S is a flexible spacer, C is a crosslinking group (preferably a photocrosslinking group), and X− are negatively charged counter ions. Ionic materials of this type may act as both electrolytes and as triplet light emitters in LEC devices. The inclusion of the rod-shaped molecular structures A and flexible spacers S in the overall structure of materials 300 is meant allow incorporation of a large percentage of materials 700 in the formulation of chiral liquid crystalline polymer materials for use in layers 608 without undesirably decreasing the stability of the chiral liquid crystalline phase of the material formulation.

A second chiral liquid crystal polymer photonic crystal similar to stack 519 in device 500 may be added to device 700 to produce a device that produces light at three or four different wavelengths.

1. A light emitting device comprising a single light emitting photonic crystal having an electroluminescent material disposed in the single light emitting photonic crystal, wherein
the single light emitting photonic crystal comprises a series of layers of chiral liquid crystalline polymer, wherein
the electroluminescent material is localized in one of the layers of chiral liquid crystalline polymer, wherein
at least one of the series of layers of chiral liquid crystalline polymer comprises a chiral liquid crystalline, charge carrier transporting polymer, wherein
the single light emitting photonic crystal further comprises a second luminescent material, wherein
energy emanating from the electroluminescent material stimulates the second luminescent material into light emission, and wherein
the light emitted by the light emitting device is a mixture of light emitted by the electroluminescent material and light emitted by the second luminescent material.

2. The light emitting device of claim 1 wherein at least one of the layers of chiral liquid crystalline polymer comprises chiral nematic liquid crystalline polymer.

3. The light emitting device of claim 1 wherein the energy emanation from the electroluminescent material and its stimulation of light emission in the second luminescent material is mediated by light emission from the electroluminescent material and the light's reabsorption by the second luminescent material.

4. The light emitting device of claim 3 wherein the second luminescent material is localized in a second layer of chiral liquid crystalline polymer that is different from a first layer of chiral liquid crystalline polymer in which the electroluminescent material is localized.

5. The light emitting device of claim 4 wherein the second layer of chiral liquid crystalline polymer is adjacent to the first layer of chiral liquid crystalline polymer in which the electroluminescent material is localized.

6. The light emitting device of claim 4 wherein the second layer of chiral liquid crystalline polymer is separated from the first layer of chiral liquid crystalline polymer, in which the electroluminescent material is localized, by one or more intermediate layers of chiral liquid crystalline polymer.

7. The light emitting device of claim 3 wherein the second luminescent material is localized in the same layer of chiral liquid crystalline polymer as is the electroluminescent material.

8. The light emitting device of claim 3 wherein the second luminescent material is located in multiple layers of chiral liquid crystalline polymer.

9. The light emitting device of claim 1 wherein the energy emanation from the electroluminescent material and its stimulation of light emission in the second luminescent material is mediated by Förster excitonic energy transfer.

10. The light emitting device of claim 9 wherein the second luminescent material is localized in a second layer of chiral liquid crystalline polymer that is different from a first layer of chiral liquid crystalline polymer in which the electroluminescent material is localized and the second layer of chiral liquid crystalline polymer is adjacent to the first layer of chiral liquid crystalline polymer.

11. The light emitting device of claim 1 wherein the energy emanation from the electroluminescent material and its stimulation of light emission in the second luminescent material is mediated by Dexter excitonic energy transfer.

12. The light emitting device of claim 11 wherein the second luminescent material is localized in a second layer of chiral liquid crystalline polymer that is different from a first layer of chiral liquid crystalline polymer in which the electroluminescent material is localized and the second layer of chiral liquid crystalline polymer is adjacent to the first layer of chiral liquid crystalline polymer.

13. The light emitting device of claim 1 wherein the series of layers of chiral liquid crystalline polymer all have a helical structure.

14. The light emitting device of claim 13 wherein the single photonic crystal structure comprises the helical structures of the series of layers of chiral liquid crystalline polymer.

15. The light emitting device of claim 13 wherein two or more of the series of layers of chiral liquid crystalline polymer have the same helical pitch to within 10%.

16. The light emitting device of claim 1 wherein the series of layers of chiral liquid crystalline polymer have an ordinary refractive index and an extraordinary refractive index.

17. The light emitting device of claim 16 wherein two or more of the series of layers of chiral liquid crystalline polymer have the same ordinary refractive index to within 10%.

18. The light emitting device of claim 16 wherein two or more of the series of layers of chiral liquid crystalline polymer have the same extraordinary refractive index to within 10%.

19. The light emitting device of claim 16 wherein two or more of the series of layers of chiral liquid crystalline polymer have the same difference between the ordinary and extraordinary refractive indices to within 10%.

20. The light emitting device of claim 1 wherein the chiral liquid crystalline polymer in each of the layers is produced by the polymerization of a mixture comprising nematic monomer materials and chiral nematic monomer dopants.

21.-36. (canceled)
